(19) United States
(12) Patent Application Publication
(10) Pub. No.: US 2004/0108134 A1
(43) Pub. Date: Jun. 10, 2004

(54) Printed wiring boards having low inductance embedded capacitors and methods of making same

(76) Inventors: William J. Borland, Cary, NC (US); Saul Ferguson, Durham, NC (US); David R. McGregor, Cary, NC (US)

Correspondence Address: E I DU PONT DE NEMOURS AND COMPANY, LEGAL PATENT RECORDS CENTER, BARLEY MILL PLAZA 25/1128, 4417 LANCASTER PIKE, WILMINGTON, DE, 19805, US

(21) Appl. No.: 10/663,551

(22) Filed: Sep. 16, 2003

Related U.S. Application Data
(60) Provisional application No. 60/433,105, filed on Dec. 13, 2002.
(60) Provisional application No. 60/418,045, filed on Oct. 11, 2002.

(51) Int. Cl. H05K 1/16

(52) U.S. Cl. 174/260; 174/255; 361/793

(57) ABSTRACT

A printed wiring board (PWB) has stacked innerlayer panels comprised of passive circuit elements. The passive elements can include capacitors with electrode terminations located within the footprints of the capacitor electrodes. The capacitor terminations are therefore closely spaced, reducing the capacitors' contributions to loop inductance in the innerlayer. Capacitor terminations within the electrode footprints also reduce the PWB board surface area used in forming the capacitors.

### RELATED APPLICATIONS

This application is related to the application assigned attorney docket number EL-0495, U.S. application Ser. No. 60/418,045, filed in the United States Patent and Trademark Office on Oct. 11, 2002, and entitled “CO-FIRED CERAMIC CAPACITOR AND METHOD FOR FORMING CERAMIC CAPACITORS FOR USE IN PRINTED WIRING BOARDS.”

### BACKGROUND

1. Technical Field

The technical field is ceramic capacitors. More particularly, the technical field includes low inductance, space efficient ceramic capacitors that may be embedded in printed wiring boards.

2. Background Art

The practice of embedding passive circuit elements in multilayer printed wiring boards (PWB) allows for reduced circuit size and improved circuit performance. The passive circuit elements are typically embedded in panels that are stacked and connected by conductive vias, with the stack of panels forming the multilayer printed wiring board. The panels can be generally referred to as “innerlayer panels.”Passive circuit elements such as capacitors embedded in an innerlayer panel contribute to the circuit loop inductance (also known as “lead inductance”). High circuit loop inductances are undesirable in most applications; and low circuit loop inductances are particularly desirable in circuits used in high-frequency and high-speed applications. A capacitor's contribution to circuit loop inductance is caused by the capacitor's self-inductance and by its termination separation. A capacitor “termination” can be generally defined as the point at which a circuit conductor, such as a conductive trace or conductive lead, is connected to a capacitor electrode or electrodes. Conventional capacitor elements have one termination located at one edge of the capacitor, and another termination located at an opposite edge of the capacitor. Conventional capacitor elements generally do not locate the terminations within a plan view surface area, or “footprint” of the capacitor electrodes. Locating the terminations at the opposite edges of a capacitor results in the highest termination separation for the capacitor, and correspondingly high loop inductances.

U.S. Pat. No. 4,687,540 to Singhdeo et al. discloses a glass capacitor 60 having high termination separation. As shown in FIG. 6 of Shinghdeo, external electrodes 66 connect to internal electrodes 62, 64 at opposite ends of the glass capacitor 60. The termination separation is thereby maximized in the capacitor 60.

In addition to low circuit loop inductances, space is also at a premium in PWB innerlayer panels. Capacitors should therefore occupy a relatively small surface area of an innerlayer panel. Locating capacitor terminations at opposite ends of a capacitor has the additional disadvantageous effect of giving the capacitor a larger overall footprint, which occupies greater space in the printed wiring board.

### SUMMARY

According to a first embodiment, a printed wiring board comprises a first circuit conductor extending through at least a part of the printed wiring board, a second circuit conductor extending through at least a part of the printed wiring board, and a plurality of stacked innerlayer panels. One or more of the innerlayer panels comprises a first electrode formed from a foil and having a termination wherein the first circuit conductor is coupled to the first electrode at the termination of the first electrode and wherein the first electrode termination is within a footprint of the first electrode, at least one dielectric disposed over the first electrode, and a second electrode spaced from the first electrode and having a termination. The second electrode, the first electrode, and the dielectric form a capacitor. The second electrode capacitor termination is preferably located within the footprint of the second electrode.

According to the first embodiment, locating the first electrode capacitor termination within the footprint of the first electrode reduces the spacing between the first electrode capacitor termination and the second electrode capacitor termination. Locating the second electrode termination within the footprint of the second electrode allows even further reduction of the termination separation. Reducing the termination separation reduces the capacitor's contribution to circuit loop inductance. Low inductance capacitors are particularly advantageous in high-frequency and high-speed PWB applications. In addition, termination connections are not required at the peripheral edges of the capacitor, which reduces the printed wiring board area occupied by the capacitor.

According to an alternative embodiment, a printed wiring board includes at least one innerlayer panel comprising a two-layer dielectric capacitor with three electrodes, the terminations of each of the electrodes being located within the respective electrode footprints. The two-layer dielectric capacitor innerlayer panel embodiment conveys the advantages of low circuit loop inductance and a reduced use of PWB board area. In addition, the two-layer dielectric capacitor embodiment has an increased capacitance density due to the additional layer of the dielectric and due to the additional electrode.

An embodiment of a method of forming a printed wiring board comprises forming a plurality of stacked innerlayer panels. At least one of the innerlayer panels can be formed by forming a dielectric over a metallic foil, forming a first electrode from the foil, the first electrode having a termination, and forming a second electrode over the dielectric, the second electrode having a termination, wherein the first electrode, the second electrode, and the dielectric form a capacitor. A first circuit conductor is formed that extends through at least a portion of the printed wiring board and contacts the first electrode termination, the first electrode termination being located within a footprint of the first electrode. A second circuit conductor is also formed. The second circuit conductor contacts the second electrode termination and extends through at least a portion of the printed wiring board. The second electrode termination may also be located within the footprint of the second electrode.

The method of forming a printed wiring board provides a printed wiring board with innerlayer panels including capacitors having a low contribution to circuit loop inductance. In addition, the innerlayer panels formed by the method occupy a relatively small board area of the printed wiring board.

### BRIEF DESCRIPTION OF THE DRAWINGS

The detailed description will refer to the following drawings, wherein like numerals refer to like elements, and wherein:

FIG. 1A is a top plan view of a stage of manufacture of a first embodiment of an innerlayer panel of a printed wiring board;

FIG. 1B is a sectional view in side elevation from FIG. 1A, taken on line 1B-1B;

FIG. 1C is a top plan view of a stage of manufacture of the first innerlayer panel embodiment;

FIG. 1D is a sectional view in side elevation from FIG. 1C, taken on line 1D-1D;

FIG. 1E is a sectional view in side elevation of a stage of manufacture of the first innerlayer panel embodiment;

FIG. 1F is a top plan view of a stage of manufacture of the first innerlayer panel embodiment, illustrating a completed innerlayer panel before conductors are coupled to the innerlayer panel terminations;

FIG. 1G is a sectional view in side elevation from FIG. 1F, taken on line 1G-1G;

FIG. 1H is a sectional view in side elevation of a first embodiment of a printed wiring board including innerlayer panels;

FIG. 1I is a sectional view in side elevation and is an isolated view of the first innerlayer panel embodiment after incorporation into the printed wiring board illustrated in FIG. 1H;

FIG. 1J is a sectional view taken along line 1J-1J in FIG. 1I;

FIGS. 2A-2C are sectional views in side elevation of stages of manufacture of a second embodiment of an innerlayer panel;

FIG. 2D is a sectional view in side elevation of the second innerlayer panel embodiment;

FIG. 3A is a sectional view in side elevation of a third embodiment of an innerlayer panel;

FIG. 3B is a sectional view from FIG. 3A, taken on line 3B-3B;

FIG. 4 is a sectional view in side elevation of a fourth embodiment of an innerlayer panel;

FIG. 5 is a sectional view in side elevation of a fifth embodiment of an innerlayer panel;

FIG. 6 is a sectional view in side elevation of a sixth embodiment of an innerlayer panel;

FIGS. 7A and 7B are sectional views in side elevation of stages of manufacture of a seventh embodiment of an innerlayer panel;

FIG. 7C is a top plan view of a stage of manufacture of the seventh innerlayer panel embodiment;

FIG. 7D is a sectional view in side elevation taken on line 7D-7D in FIG. 7C; and

FIG. 7E is a sectional view in side elevation of the completed seventh innerlayer panel embodiment.

### DETAILED DESCRIPTION

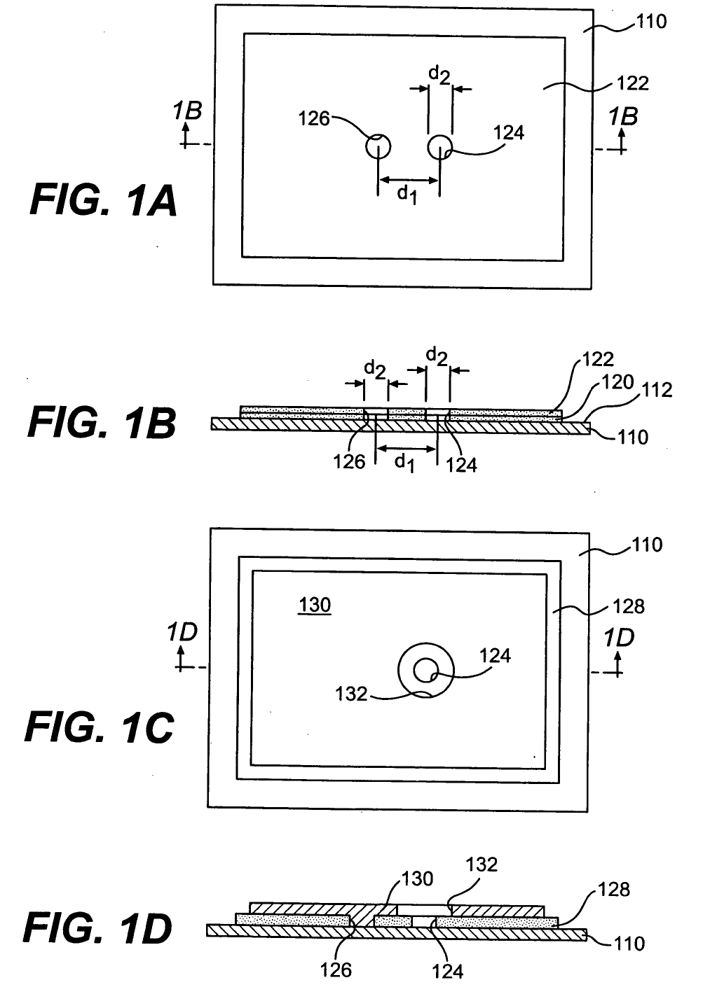

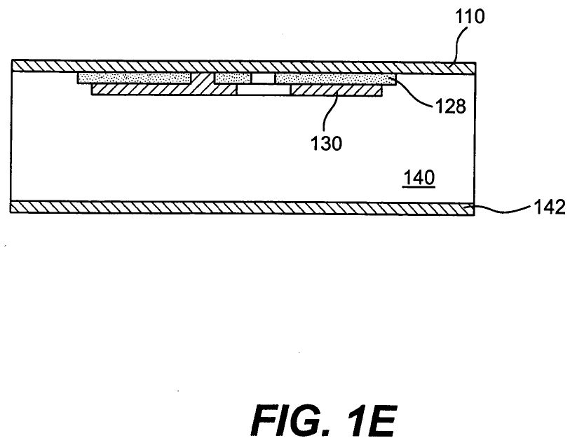

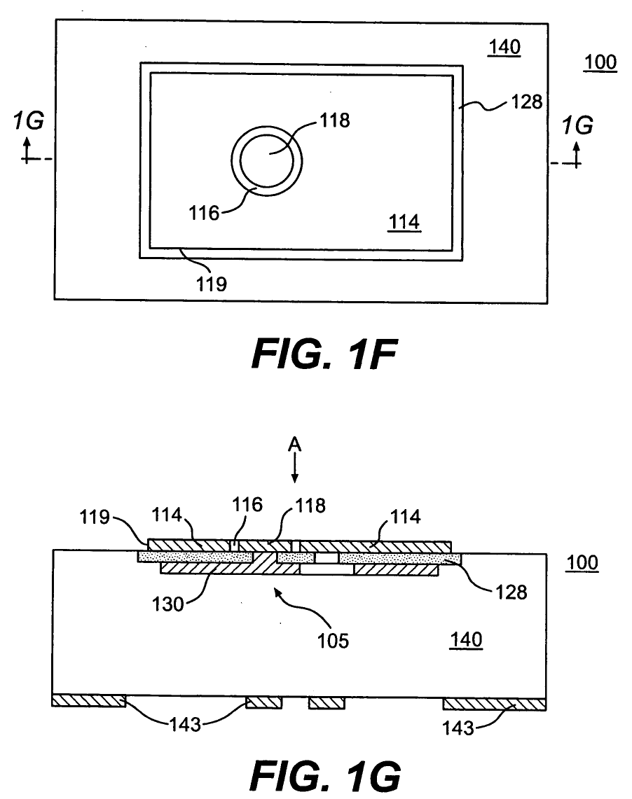

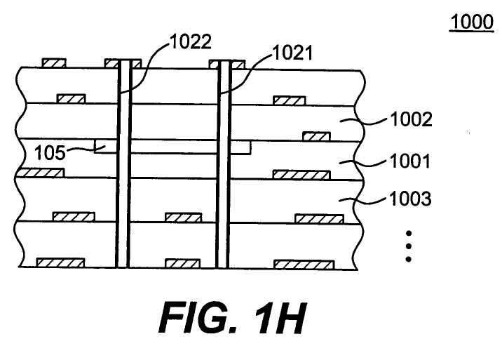

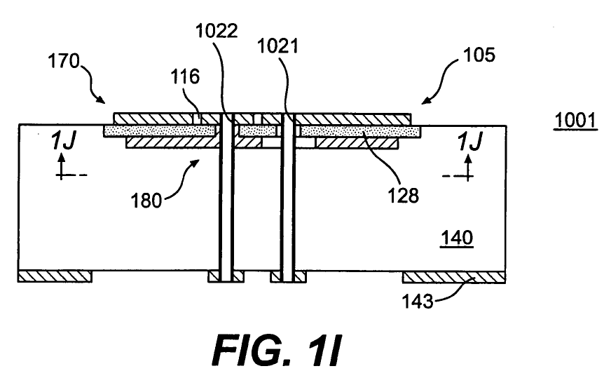

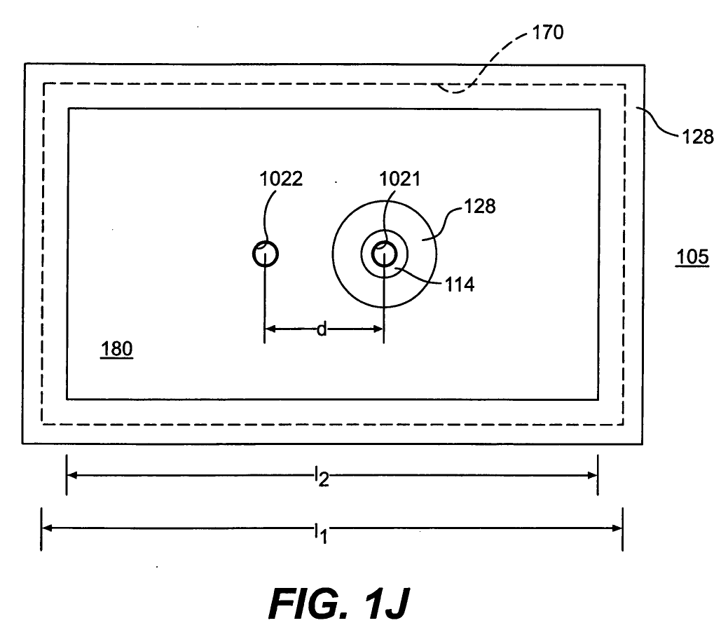

FIGS. 1A-1G illustrate a general method of manufacturing a printed wiring board 1000 (FIG. 1H). FIG. 1H illustrates the completed printed wiring board 1000, which comprises stacked layers 1001, 1002, 1003, . . . having embedded circuit elements. The stacked layers 1001, 1002, 1003 . . . can be generally referred to as “innerlayer panels.” FIGS. 1A-1G illustrate a method of manufacturing a first embodiment of an innerlayer panel 100 before the innerlayer panel 100 is incorporated into the printed wiring board 1000. FIG. 1I is an isolated view of an innerlayer panel 1001, which corresponds to the innerlayer panel 100 after the innerlayer panel 100 has been incorporated into the printed wiring board 1000.

FIGS. 1A-1G illustrate the steps in manufacturing the innerlayer panel 100 having a capacitor 105 (the finished innerlayer panel 100 is shown in FIG. 1G). A specific example of an innerlayer panel 100 is also described in detail below. A single capacitor 105 is formed by the method described below. However, each of the innerlayer panels 1001, 1002, 1003 . . . can include a number of individual capacitors of differing type and arranged in various ways in the innerlayer panel 100, in addition to other passive elements. The printed wiring board 1000 illustrated in FIG. 1H may also comprise any number of stacked innerlayer panels and conductive interconnections between the panels.

FIGS. 1A and 1B illustrate a first stage of manufacture of the innerlayer panel 100. FIG. 1A is a top plan view, and FIG. 1B is a sectional view in side elevation from FIG. 1A, taken on line 1B-1B. In FIGS. 1A and 1B, a metallic foil 110 is provided. The foil 110 may have a large surface area and can be used to produce a large number of passive components such as capacitors. The foil 110 may be of a type generally available in the printed wiring board industry. For example, the foil 110 may be copper, copper-invar-copper, invar, nickel, nickel-coated copper, or other metals that have melting points in excess of the firing temperature for thick film pastes. Preferred foils include foils comprised predominantly of copper, such as reverse-treated copper foils, double-treated copper foils, and other foils commonly used in the multilayer printed wiring board industry. The thickness of the foil 110 may be in the range of, for example, about 1-100 microns, preferably 3-75 microns, and most preferably 12-36 microns, corresponding to between about ⅓ oz and 1 oz copper foil.

The foil 110 may be pretreated by applying an underprint 112. The underprint 112 is a relatively thin layer applied to a component-side surface of the foil 110. In FIG. 1B, the underprint 112 is indicated as a surface coating on the foil 110. The underprint 112 adheres well to the metal foil 110 and to layers deposited over the underprint 112. The underprint 112 may be formed, for example, from a paste applied to the foil 110 that is fired at a temperature below the softening point of the foil 110. The paste may be printed as an open coating over the entire surface of the foil 110, or printed on selected areas of the foil 110. It is generally more economical to print the underprint paste over selected areas of the foil. However, when a copper foil 110 is used in conjunction with a copper underprint 112, glass in the copper underprint paste retards oxidative corrosion of the copper foil 110, and it may therefore be preferable to coat the entire surface of the foil 110 if oxygen-doped firing is utilized.

Referring to FIG. 1B, a dielectric material is screen-printed onto the pretreated foil 110, forming a first dielectric layer 120 over the foil 110. The dielectric material may be, for example, a thick-film dielectric ink. The dielectric ink may be formed of, for example, a paste.

The first dielectric layer 120 is dried, and a second dielectric layer 122 is applied, and dried. A first aperture 124 and a second aperture 126 are included in the respective dielectric layers 120, 122 during forming. The apertures 124, 126 may also be referred to as “through-holes” or “clearance holes.” In the embodiment illustrated in FIGS. 1A and 1B, the apertures 124, 126 are circular as shown in the top plan view of FIG. 1A. Other shapes, such as polygonal shapes, for example, are also possible. The circular apertures 124, 126 illustrated in the embodiment of FIGS. 1A and 1B are spaced at a distance d, and each aperture has a diameter of d₂. The aperture diameter d₂ may be, for example, larger than a drill or laser spot size that will be used to subsequently create a via in the manufactured article. Via formation is discussed below with reference to FIG. 1H. The diameters of the apertures 124, 126 need not, however, be identical. The distance d₁ may be selected, for example, to equal the distance d₂ plus an additional increment. The incremental distance is preferably selected to maintain a minimal desired separation of the first and second apertures 124, 126.

In an alternative embodiment, a single layer of dielectric material may instead be deposited through a coarse mesh screen to provide an equivalent thickness dielectric layer in a single screen-printing step.

A conductive layer 130 is formed over the second dielectric layer 122 and dried. The conductive layer 130 can be formed by, for example, screen-printing a thick-film metallic ink. The conductive layer 130 is formed with an aperture 132 aligned over the first aperture or through-hole 124. The aperture 132 preferably is concentric with the aperture 124, but other arrangements may be satisfactory for circular and other polygonal shaped apertures. The aperture 132 is larger in surface area than the first aperture 124. A portion of the conductive layer 130 extends through the second aperture 126 and contacts the foil 110.

The first dielectric layer 120, the second dielectric layer 122, and the conductive layer 130 are then fired. The post-fired article is shown in FIGS. 1C and 1D. Firing the dielectric layers 120, 122 and the conductive layer 130 at the same time, without first firing the dielectric layers 120, 122, may be referred to as “co-firing” the dielectric and conductive layers. A dielectric 128 results from the co-firing. The thick-film dielectric layers 120, 122 may be formed of, for example, a high dielectric constant functional phase such as barium titanate and a dielectric property-modifying additive such as zirconium dioxide, mixed with a glass-ceramic frit phase. During co-firing, the glass-ceramic frit phase softens, wets the functional and additive phases and coalesces to create a dispersion of the functional phase and the modifying additive in a glass-ceramic matrix. At the same time, metallic electrode powders of the conductive layer 130 are wetted by the softened glass-ceramic frit phase and the separate phases sinter together. In general, as shown in FIG. 1C, the surface area of the dielectric 128 should be larger than that of the conductive layer 130.

In FIG. 1E, the resulting article is inverted and laminated to laminate material 140. The component-side face of the foil 110, which contacts the dielectric 128, is laminated to the laminate material 140. The lamination can be performed, for example, using FR4 prepreg in standard printing wiring board processes. In one embodiment, a 106 epoxy-type prepreg may be used. A foil 142 may be applied to the laminate material 140 to provide a surface for creating circuitry, such as, for example, a signal layer.

The dielectric prepreg and laminate materials can be any type of dielectric material such as, for example, standard epoxy, high Tg epoxy, polyimide, polytetrafluoroethylene, cyanate ester resins, filled resin systems, BT epoxy, and other resins and laminates that provide insulation between circuit layers.

After lamination, a photoresist is applied to the foil 110 and to the foil 142 shown in FIG. 1E and the foils 110 and 142 are imaged, etched, and the photoresists are stripped using, for example, standard printing wiring board processes and conditions. The etching step results in the innerlayer panel 100. FIG. 1F is a plan view of the innerlayer panel 100. FIG. 1F is seen from the direction of arrow A in FIG. 1G. FIG. 1G is a sectional view taken on line 1G-1G in FIG. 1F. The innerlayer panel 100 can be laminated to other printed wiring board cores using prepreg and standard lamination conditions to form a multilayer printed wiring board.

The etching step results in a trench 116 that isolates a first portion 114 of the etched foil from a second portion 118. The portions 114 and 118 are what remains of the foil 110 after etching. The trench 116 also breaks electrical contact between the first conductive layer 130 and the first portion 114. As shown in FIG. 1F, a peripheral edge 119 is also etched back so that the dielectric 128 is slightly larger in surface area than the first portion 114. The conductive layer 130 remains in contact with the second portion 118. Etching the foil 142 results in circuitry 143 that may subsequently be used to connect to capacitor terminations.

Referring to FIG. 1H, the imaged innerlayer panel 100 shown in FIGS. 1F and 1G is laminated together with other imaged innerlayer panels. FIG. 1H illustrates a sectional view, in side elevation, of a completed printed wiring board 1000. The printed wiring board 1000 comprises innerlayer panels 1001, 1002, 1003 . . . . The innerlayer panel 1001 is a schematic representation of the innerlayer panel 100 formed from the method described above, after incorporation of the innerlayer panel 100 into the printed wiring board 1000. A block representation of the capacitor 105 is also illustrated in the innerlayer panel 1001.

The innerlayer panels used to form the printed wiring board 1000 can be laminated together in a lamination pressing. The innerlayer panels can be bonded together using, for example, dielectric prepregs. Each of the innerlayer panels can have a different design, including differing arrangements of circuit elements. The term “innerlayer panel” does not imply that the panels must be sandwiched in the interior of the printed wiring board 1000, and the innerlayer panels can also be located at the ends of the printed wiring board 1000. The printed wiring board 1000 may be laminated in multiple stages. For example, subassemblies of innerlayer panels may be processed and laminated, and one or more subassemblies can subsequently be laminated together to form the finished printed wiring board 1000.

The innerlayer panels 1001, 1002, 1003 . . . comprising the printed wiring board 1000 may be connected by interconnection circuitry generally referred to as “circuit conductors.” The circuit conductors can be formed, for example, after all of the innerlayer panels have been laminated together. Alternatively, circuit conductors can be formed in subassemblies of innerlayer panels or in individual panels prior to incorporating all of the innerlayer panels 1001,1002, 1003 . . . into the completed printed wiring board 1000.

The interconnection circuitry between innerlayers can include, for example, one or more conductive vias, extending through all or a part of the printed wiring board 1000. In FIG. 1H, first and second circuit conductors 1021, 1022, extend through the entire printed wiring board 1000, and have the form of through-hole conductive vias. The first and second conductive vias 1021, 1022 can be formed, for example, by laser or mechanical drilling through the laminated innerlayer panels. The holes formed by drilling are then plated with a conductive material. The resulting conductive vias 1021, 1022, which extend through the entire printed wiring board 1000, are typically referred to as “plated through-holes,” and are usually formed after all of the innerlayer panels have been laminated together.

Circuit conductors may also extend through subassemblies of innerlayer panels or through individual panels. Via circuit conductors extending through only a part of the printed wiring board 1000 are commonly referred to as “buried vias.” Buried vias are typically drilled and plated through a subassembly of innerlayer panels before the subassembly of innerlayer panels is incorporated into a printed wiring board by lamination. A conductive via formed in an individual innerlayer panel is commonly referred to as a “microvia,” and may be used, for example, to terminate a capacitor within an innerlayer panel.

After all interconnections have been formed and all subassemblies of innerlayer panels or individual innerlayer panels have been laminated together, the printed wiring board 1000 is complete. In FIG. 1H, the printed wiring board 1000 is illustrated as comprising the innerlayer panels 1001, 1002, 1003 . . . in a stacked configuration and laminated and connected by the circuit conductors 1021, 1022. Any number of innerlayer panels, however, may be included in a printed wiring board according to the present embodiments.

FIG. 1I is an exploded, isolated view of the innerlayer panel 1001 shown in FIG. 1H. FIG. 1I also illustrates a portion of the first circuit conductor 1021 and a portion of the second circuit conductor 1022, which may extend through the printed wiring board 1000 as illustrated in FIG. 1H. The innerlayer panel 1001 includes the finished capacitor 105, with electrode terminations connected to the first and second circuit conductors 1021, 1022.

After forming the circuit conductors 1021,1022, what used to be the portion 114 (FIG. 1G) forms a first electrode 170. The first electrode 170 is electrically coupled to the first circuit conductor 1021. What used to be the conductive layer 130 and the portion 118 (FIG. 1G) form a second electrode 180 which is electrically coupled to the second circuit conductor 1022.

One completed capacitor 105 is illustrated as part of the completed innerlayer panel 1001. A number of capacitors, however, and other circuit components of various design and arranged in various patterns, can be included in the embodiment of the innerlayer panel 1001.

The first and second circuit conductors 1021, 1022 illustrated in FIG. 1I are shown as sections of the first and second plated through-hole vias 1021, 1022 illustrated in FIG. 1H. However, the circuit conductors in the innerlayer panel 1001 can also be, for example, buried vias extending through a subassembly of innerlayer panels in the printed wiring board 1000. The first and second circuit conductors 1021, 1022 can also be, for example, vias that extend only through the innerlayer panel 1001, such as microvias used to terminate the capacitor 105.

FIG. 1J is a sectional view taken along line 1J-1J in FIG. 1I. FIG. 1J and illustrates the capacitor 105 in plan view. As shown in FIGS. 1I and 1J, the termination of the first electrode 170 is located at a through-hole aperture of the dielectric 128, where the first circuit conductor 1021 electrically couples to the first electrode 170. The termination of the second electrode 180 is located where the second circuit conductor 1022 couples to the second electrode 180. Referring specifically to FIG. 1J, the terminations of the electrodes 170, 180 are located within the plan surface area, or “footprints” of the respective electrodes 170, 180.

The spacing of the terminations of the electrodes 170, 180 is illustrated as d, a width of the first electrode 170 is I₁ and a width of the second electrode 180 is I₂. The spacing d of the terminations corresponds to the spacing d₁ illustrated in FIG. 1A. In the embodiments described in this specification, the termination spacing d can be much smaller than the widths I₁, I₂ of the first electrode 170 and the second electrode 180. For example, the spacing d may be less than half of the widths I₁, I₂. The spacing d may be selected to be equal to, for example, the sum of the radii of the apertures of the via conductors 1021, 1022, plus an additional increment that is determined by, for example, screen printing registration capabilities. The additional increment may be generally selected in order to maintain a preferred or minimum amount of dielectric between the apertures to provide a margin of error for registration issues inherent in screen printing.

According to the above embodiment, the terminations located within the electrode footprints may be spaced relatively closely to one another, reducing the contribution to circuit inductance by the capacitor 105.

The following example illustrates particular materials and processes used in practicing the general method of manufacturing the printed wiring board 1000 illustrated in FIGS. 1A-1J.

### EXAMPLE 1

Referring to FIGS. 1A-1E, a specific embodiment of the innerlayer panel 1001 will now be described. In this example, the foil 110 is a copper foil. The type of copper foil 110 was commercial grade 1 ounce copper foil. The copper foil 110 was pretreated by applying a copper underprint paste over selected areas of the foil 110. The resulting product was then fired in nitrogen at 900° C. for 10 minutes at peak temperature, with a total cycle time of approximately 1 hour, forming the underprint 112.

In FIGS. 1A and 1B, a thick-film dielectric ink was screen-printed onto the pretreated copper foil 110 through a 400 mesh screen to create a 198 mm×230 mm first dielectric layer 120. The wet printed thickness of the first dielectric layer 120 was approximately 12-15 microns. The first dielectric layer 120 was dried at 125° C. for approximately 10 minutes, and a second dielectric layer 122 was applied by screen-printing also through a 400 mesh screen, followed by another drying step at 125° C. The thick-film dielectric ink included a barium titanate component, a zirconium oxide component, and a glass-ceramic phase. The spacing d₁ of the first and second apertures 124, 126 was approximately 41 mils. The diameter d₂ of the apertures 124, 126 was approximately 26 mils.

Referring to FIGS. 1C and 1D, a thick-film copper electrode ink layer 130 was printed through 400 mesh screens onto the dielectric layer 122, and dried at 125° C. for approximately 10 minutes. Referring to FIG. 1C, the layer 130 had plan dimensions of about 178 mm×210 mm. The size of the layer 130 was approximately 10 mils smaller around its peripheral edge than the dielectric 128. The thickness of the printed conductive layer 130 was in the range of 5 microns. The resulting structure was then co-fired to 900° C. for 10 minutes at peak temperature using a thick film nitrogen profile. The nitrogen profile included less than 50 ppm oxygen in the burnout zone, and 2-10 ppm oxygen in the firing zone, with a total cycle time of 1 hour.

Referring to FIG. 1E, a FR4 printed wiring board substrate laminate material 140 was laminated to the component side of the foil 110. A copper foil 142 was formed over the laminate material 140. The lamination conditions were 185° C. at 208 psig for 1 hour in a vacuum chamber evacuated to 28 inches of mercury. A silicone rubber press pad and a smooth PTFE-filled glass release sheet were in contact with the foil 110 to prevent the epoxy from gluing the lamination plates together.

Referring to FIGS. 1F and 1G, the foils 110 and 142 each had a photoresist applied and were imaged and etched and the photoresists were stripped to form an innerlayer panel 100. The trench 116 had an inside diameter of approximately 36 mils and an outside diameter of approximately 46 mils.

Referring to FIG. 1H, a printed wiring board 1000 was then formed using the innerlayer panel 100. To form the printed wiring board 1000, the innerlayer panel 100 was laminated together with other innerlayer panels in a stacked configuration. Each of the innerlayer panels incorporated in the printed wiring board 1000 contained interconnection circuitry, and the circuit components in the innerlayer panels were connected to buried vias, through-hole vias, or both. The circuit conductors 1021, 1022 were formed by drilling 16 mil (16/1000 inch) diameter through-holes, and plating the via walls with copper to a thickness of approximately 25 microns (1 mil or 1/1000 inch).

Referring to FIG. 1I, the first and second vias 1021, 1022 were coupled to the first and second electrodes 170, 180, respectively.

In this example, the thick film dielectric material had the following composition:

| | |
|---|---|
| Barium titanate powder | 64.18% |
| Zirconium oxide powder | 3.78% |
| Glass A | 11.63% |
| Ethyl cellulose | 0.86% |
| Texanol | 18.21% |
| Barium nitrate powder | 0.84% |
| Phosphate wetting agent | 0.5%. |
| Glass A comprised: | |
| Germanium oxide | 21.5% |
| Lead tetraoxide | 78.5%. |

The Glass A composition corresponded to Pb₅Ge₃O₁₁, which precipitated out during co-firing, and had a dielectric constant in the range of approximately 70-150. The thick film copper electrode ink comprised:

| | |
|---|---|
| Copper powder | 55.1% |
| Glass A | 1.6% |
| Cuprous oxide powder | 5.6% |
| Ethyl cellulose T-200 | 1.7% |
| Texanol | 36.0%. |

The capacitor designs exemplified by the above first embodiment and its alternatives provide for reduced termination separation, and accordingly provide for a low contribution to circuit loop inductance. Low inductance circuits are desirable in a variety of applications. For example, low inductance circuits are particularly desirable in high-frequency and high-speed applications. In addition, according to the above first embodiment and its alternatives, termination connections are not required at the peripheral edges of the capacitor. This aspect reduces the printed wiring board area required to accommodate the capacitor. This feature allows for a greater number of capacitors to be incorporated into a printed wiring board. Alternatively, a printed wiring board requiring specified capacitances can be smaller in size than a printed wiring board having capacitor terminations at electrode peripheral edges.

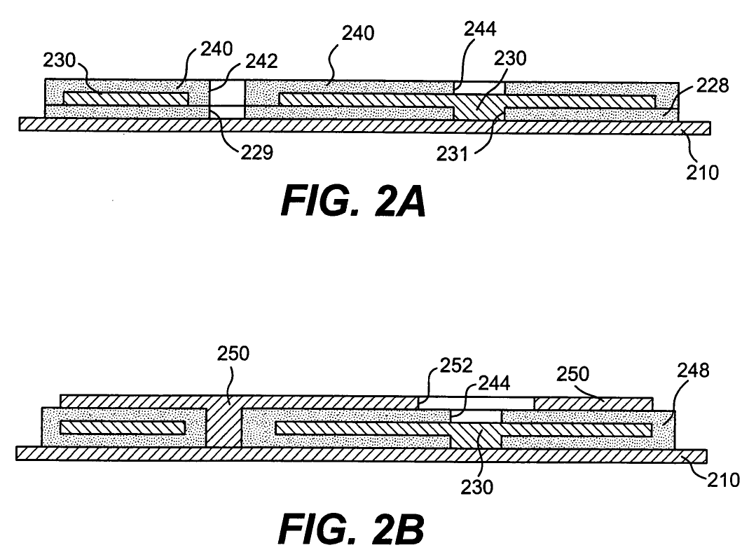

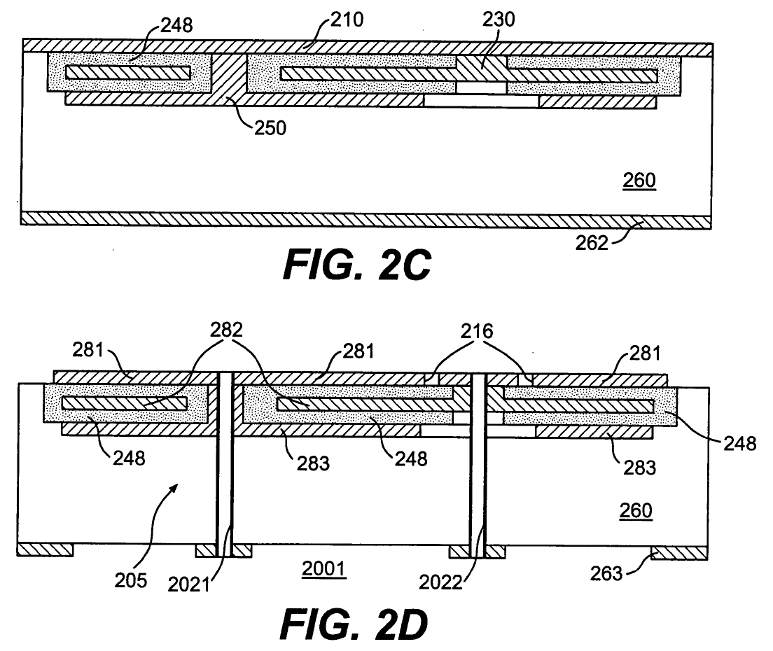

FIGS. 2A-2D illustrate a method of manufacturing a second embodiment of an innerlayer panel 2001. The finished capacitor innerlayer panel 2001 includes a capacitor 205 and is illustrated as an isolated, exploded sectional view in FIG. 2D. The innerlayer panel 2001 may be incorporated into a multilayer printed wiring board, such as the printed wiring board 1000 illustrated in FIG. 1H. The innerlayer panel 2001 has two layers of dielectric and three electrodes. The two-layer dielectric design provides a high capacitance density for the capacitor 205. The two-layer dielectric can provide, for example, at least double the capacitance density when compared to single-layer capacitor designs.

FIG. 2A is a sectional view of a stage of manufacture of the innerlayer panel 2001 illustrated in FIG. 2D. The article shown in FIG. 2A comprises a foil 210, a first dielectric layer 228, and a first conductive layer 230. The first dielectric layer 228 includes a first aperture 229 and a second aperture 231. The article in FIG. 2A may correspond generally to the article shown in FIG. 1D, and can be manufactured in a similar manner. In addition, however, a second dielectric layer 240 is formed over the conductive electrode layer 230, and dried. The second dielectric layer 240 is formed with first and second apertures 242, 244 aligned over the first and second apertures 229 and 231, respectively. The first and second apertures 229, 231 and 242, 244 can have, for example, a circular shape when viewed from a top plan perspective. Other shapes, such as polygonal shapes, may also be used.

Referring to FIG. 2B, a second conductive layer 250 is formed over the dielectric layer 240. The second conductive layer 250 includes an aperture 252 coincident with the aperture 244. The resulting article is then fired. Co-firing of the conductive layer 250 and the dielectric layer 240 is a preferred method of firing. FIG. 2B shows the post-fired article. Firing results in a single dielectric 248 formed from the dielectric layers 228 and 240, because the boundary between the dielectric layers 228 and 240 is effectively removed during co-firing. The single dielectric 248 can be described as a “two-layer” dielectric because it acts to separate three electrodes in the finished innerlayer panel 2001.

In this embodiment, firing can be performed in one or more instances. For example, the article can be co-fired (i.e., the dielectric layer 228 under the conductive layer 230 is not pre-fired) after the first conductive layer 230 is formed, and fired again after the second conductive layer 250 is formed. Alternatively, the article can be co-fired for the first time after the second conductive layer 250 is formed.

The component-side face of the foil 210 is laminated to laminate material 260 as shown in FIG. 2C. The laminate material 260 can have, for example, a composition similar to the laminate materials discussed above with reference to FIGS. 1A-1J. A foil 262 may be applied to the laminate material 260 which may be used to provide a surface for creating circuitry and connections to the capacitor electrodes.

Referring to FIG. 2C and to FIG. 2D, after lamination, a photoresist is applied to the foil 210 and to the foil 262. The foils 210 and 262 are then imaged, etched, and the photoresists are stripped. The foil 210 is preferably etched to a size smaller than the dielectric 248, similar to the etching process for the foil 110 illustrated in FIG. 1F. A trench 216 is also etched in the foil 210. The trench 216 may be, for example, annular, similar to the trench 116 illustrated in FIG. 1F. The resulting innerlayer panel 2001 is illustrated in FIG. 2D.

FIG. 2D is a sectional view in side elevation of the finished innerlayer panel 2001, including the capacitor 205. The innerlayer panel 2001 is suitable for integration into a printed wiring board, and the innerlayer panel 2001 in FIG. 2D is illustrated separately from a multilayer printed wiring board for the purposes of showing detail in the innerlayer panel 2001. The innerlayer panel 2001 may also be incorporated into a subassembly of innerlayer panels.

The foil 262 (FIG. 2C) may be etched to create circuitry 263 (FIG. 2D) that may be used to connect to the terminations of the capacitor 205. After etching, the resulting article may be laminated together with other innerlayer panels containing circuitry such as passive circuit elements, thereby forming a multilayer printed wiring board, or, a subassembly of innerlayer panels for use in a multilayer printed wiring board. In FIG. 2D, a first circuit conductor 2021 and a second circuit conductor 2022 are formed to extend through the innerlayer panel 2001. The first and second circuit conductors 2021, 2022 can be, for example, through-hole plated vias that are formed after the innerlayer panel 2001 is incorporated into a printed wiring board. The first and second circuit conductors 2021, 2022 can also be buried vias that extend through a subassembly of innerlayer panels including the innerlayer panel 2002. Alternatively, the circuit conductors 2021, 2022 can be microvias that extend only through the innerlayer panel 2001. Microvias can be formed prior to incorporation of the innerlayer panel 2001 into a subassembly of innerlayer panels.

After etching of the foil 210 and after forming the first and second circuit conductors 2021, 2022, the capacitor 205 (FIG. 2D) comprises a first electrode 281, a two-layer dielectric 248, a second electrode 282, and a third electrode 283. The first electrode 281 and the third electrode 283 are electrically connected to one another, and are also electrically connected to the first circuit conductor 2021. The second electrode 282 is electrically connected to the second circuit conductor 2022. The second electrode 282 is electrically isolated from the first electrode 281 by the trench 216.

As shown in FIG. 2D, the termination of the first electrode 281 and the third electrode 283 are located at through-hole apertures of both of the dielectric layers contained in the two-layer dielectric 248, where the first circuit conductor 2021 is electrically coupled to the first and third electrodes 281, 283. Similarly, the termination of the second electrode 282 is located where the second circuit conductor 2022 is electrically coupled to the second electrode 282, at a through-hole aperture in both of the dielectric layers contained in the dielectric 248. Advantageously, the terminations of the first electrode 281, the second electrode 282, and the third electrode 283 may all be located within the footprints of their respective electrodes.

The three-electrode/two-layer dielectric capacitor 205 has a high capacitance density in addition to a low contribution to circuit loop inductance. The low contribution to circuit loop inductance is due to the reduced termination separation achieved by locating the capacitor terminations within the footprints of their respective capacitor electrodes. In addition, capacitor termination connections are not required on the peripheral edges of the capacitor 205, which reduces the PWB board area occupied by the capacitor 205.

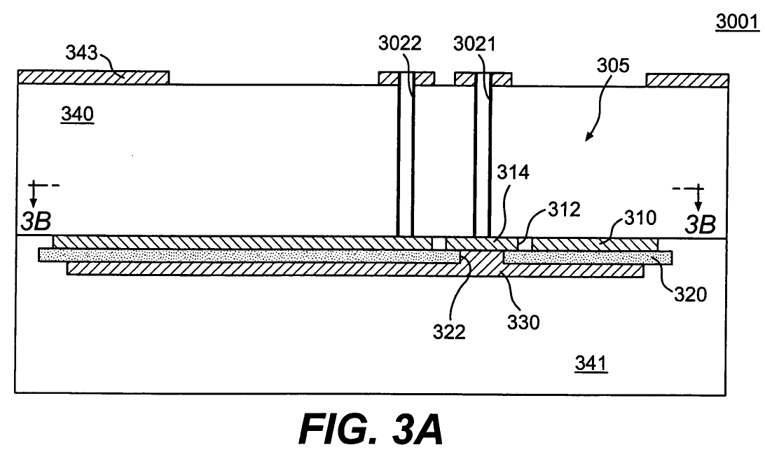

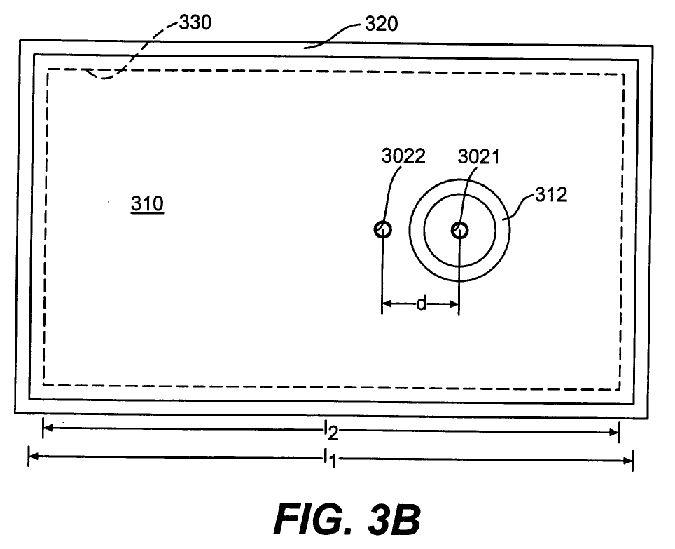

FIG. 3A is a sectional view in side elevation of a third embodiment of a capacitor innerlayer panel 3001 having a capacitor 305. The capacitor 305 has a first electrode 310 formed from a foil, a dielectric 320, and a second electrode 330. A trench 312 isolates the first electrode 310 from the second electrode 330. The capacitor 305 may generally correspond in configuration to the capacitor 105 illustrated in FIG. 1H, except that only one clearance hole or aperture 322 is required in the dielectric 320. No clearance hole is required in the second electrode 330 for a first circuit conductor 3021 to be connected to the first electrode 310. Instead, the first circuit conductor 3021 and a second circuit conductor 3022 extend from a side of the first electrode 310 that is opposite to the component side of the first electrode 310.

The innerlayer panel 3001 can be formed in a manner similar to the innerlayer panel 1001 illustrated in FIGS. 1A-1J. A dielectric layer, corresponding to the dielectric 320, is deposited over a foil, and a conductive layer, corresponding to the second electrode 330, is deposited over the dielectric layer. The dielectric layer can be formed in, for example, one or two screen printing steps. The dielectric layer and the conductive layer are then co-fired and the resulting article is laminated, component face down, to a laminate material 341 to form a laminate structure. Photoresist is then applied to the foil 310 and the foil 310 is etched to form the trench 312, thereby forming the first electrode 310 by separating it from the second electrode 330.

The article can then be laminated to laminate material 340, with a “foil side” (i.e., the side opposite to the component side) of the first electrode 310 facing the laminate material 340. A foil is applied to the laminate material 340, which may be etched to form circuitry 343. The first circuit conductor 3021 and the second circuit conductor 3022 are then formed in the resulting article. The innerlayer panel 3001 is then complete and can be incorporated into a multilayer printed wiring board, or combined with other innerlayer panels to form a multilayer subassembly. In general, an innerlayer panel containing two layers, such as the innerlayer panel 3001 having laminate layers 340 and 341, can also be referred to as a “subassembly.” In this specification, the term “innerlayer panel” is used as a general term to indicate panels which are laminated on either one or two sides of the foil electrode.

The first and second circuit conductors 3021, 3022 can be formed, for example, using a CO₂ laser so as to terminate the first and second circuit conductors 3021, 3022 at the first and second electrodes 310, 330 without damaging the electrodes 310, 330. The holes formed by the drilling operation are then plated with a conductive material to form the first and second circuit conductors 3021, 3022. The first and second circuit conductors 3021, 3022 are illustrated as plated vias.

As shown in FIG. 3A, the dielectric 320 needs only one clearance through-hole 322 so that the second electrode 330 may contact a portion 314 of the foil 310.

FIG. 3B is a sectional view taken along line 3B-3B in FIG. 3A. The terminations of the first and second electrodes 310, 330 (the second electrode 330 being indicated by a dashed line), where the first and second circuit conductors 3021, 3022 contact the electrodes 310, 330, respectively, are located within the footprints of the first and second electrodes 310, 330. The spacing of the terminations of the electrodes 310, 330 is illustrated as d, a width of the first electrode 310 is I₁, and a width of the second electrode 330 is I₂. In this embodiment, and in the other embodiments described in this specification, the termination spacing d may advantageously be much smaller than the widths I₁, I₂ of the first and second electrodes 310, 330, which reduces the contribution to circuit loop inductance from the capacitor 305. The use of printed wiring board area is also reduced because connections are not required at the edges of the electrodes 310, 330.

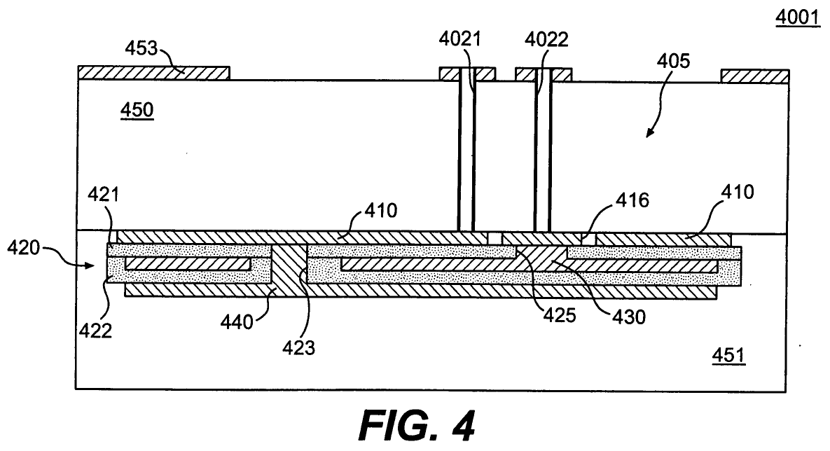

FIG. 4 is a sectional view in side elevation of a fourth embodiment of an innerlayer panel 4001 having a capacitor 405. The capacitor 405 has a two-layer dielectric layer and three electrodes. The innerlayer panel 4001 may be incorporated into a printed wiring board, such as the printed wiring board 1000 illustrated in FIG. 1H, or into a subassembly of innerlayer panels.

The capacitor 405 has a first electrode 410 formed from a foil, a two-layer dielectric 420, a second electrode 430, and a third electrode 440. The first electrode 410 is isolated from the second electrode 430 by a trench 416. The third electrode 440 is electrically coupled to the first electrode 410 through a clearance hole aperture 423 extending through both layers of the two-layer dielectric 420. The first electrode 410 is electrically coupled to a first circuit conductor 4021. The second electrode 430 is electrically coupled to a second circuit conductor 4022. The capacitor 405 is laminated on one side with laminate material 451. The article may also be laminated with a laminate material 450, so that the innerlayer panel 4001 is a “subassembly,” as discussed above. Alternatively, the article can be incorporated directly into a printed wiring board without lamination to the laminate material 450. If the laminate material 450 is used in the innerlayer panel 4001, circuitry 453 may be formed from a foil over the laminate material 450. The circuitry 453 is included so that connections may be made to the capacitor 405 terminations by way of the first and second circuit conductors 4021 and 4022.

The capacitor 405 generally corresponds in configuration to the capacitor 205 illustrated in FIG. 2D, except that a clearance through-hole is not required in the third electrode 440. The first and second conductive vias 4021, 4022 instead extend from the foil side of the first electrode 410.

The capacitor 405 of the innerlayer panel 4001 can be formed in a manner similar to the capacitor 205 of the innerlayer panel 2001 illustrated in FIG. 2D. A first dielectric layer, indicated by reference numeral 421, is formed over a foil in one or two screen printing steps. The dielectric layer 421 is then dried. A first conductive layer, corresponding to the second electrode 430, is formed over the first dielectric layer 421. The resulting article is then co-fired. A second dielectric layer, indicated by reference numeral 422, is formed over the first conductive layer and dried. A second conductive layer, corresponding to the third electrode 440, is then formed over the second dielectric layer 422. The resulting article is then co-fired.

Co-firing generally results in a single two-layer dielectric structure 420. In FIG. 4, the separate dielectric layers 421, 422 are shown to illustrate the steps involved in the method of making the capacitor 405, and co-firing will generally remove the boundaries between dielectric layers.

After co-firing, the foil is laminated component face down with a laminate material 451. The foil is then imaged, etched and stripped to form the first electrode 410 and to isolate the first electrode 410 from the second electrode 430. As shown in FIG. 4, the two-layer dielectric 420 has two clearance holes. A clearance hole 423 allows the third electrode 440 to electrically connect with the foil first electrode 410, and a clearance hole 425 allows the second electrode 430 to electrically connect with the portion 416 of the foil.

The resulting article may then be laminated with a laminate material 450, and a foil formed over the laminate material 450. The foil may be etched to form circuitry 453. The circuit conductors 4021, 4022 can be formed, for example, only in the innerlayer panel 4001, or through a printed wiring board including the innerlayer panel 4001. The circuitry 453 can allow electrical connections to the capacitor 405 terminations by way of the first and second circuit conductors 4021, 4022. The innerlayer panel 4001 is preferably laminated into a multilayer printed wiring board with other innerlayer panels containing interconnection circuitry. The first and second circuit conductors 4021, 4022 can be formed, for example, by laser drilling and plating to form conductive vias.

The terminations of the electrodes 410, 430 are located within the footprints of the electrodes 410, 430, rather than at the electrodes' edges. Also, the circuit conductors 4021, 4022 that connect to the terminations of the electrodes 410, 430 extend outward from the foil side of the first electrode 410, rather than from the electrode edges. The capacitor 405 therefore has the advantages of reduced termination separation, and reduced PWB board area size.

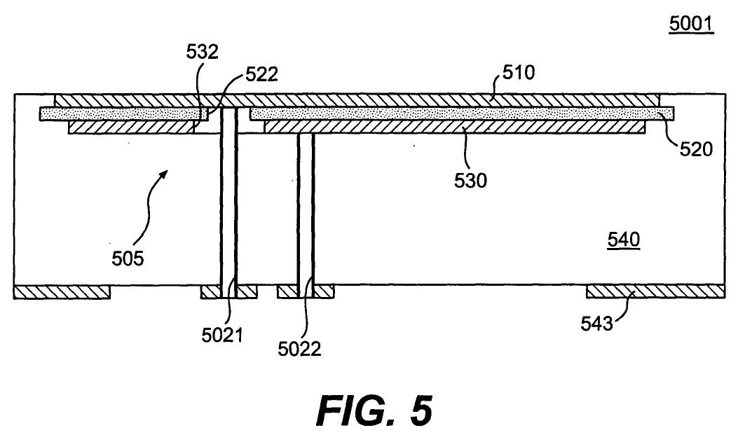

FIG. 5 is a sectional view of a fifth embodiment of a capacitor innerlayer panel 5001 including a capacitor 505. The capacitor 505 includes a first electrode 510 formed from a foil, a dielectric 520, and a second electrode 530. The capacitor 505 is laminated to a laminate material 540, and circuitry 543 may be disposed on the laminate material 540 to allow connections to the capacitor 505 terminations by way of first and second circuit conductors 5021, 5022.

The first electrode 510 is coupled to the first circuit conductor 5021, and the second electrode 530 is coupled to the second circuit conductor 5022. The termination of the first electrode 510 is located at a through-hole aperture 522 in the dielectric 520 that is coincident with a through-hole aperture 532 in the second electrode 530.

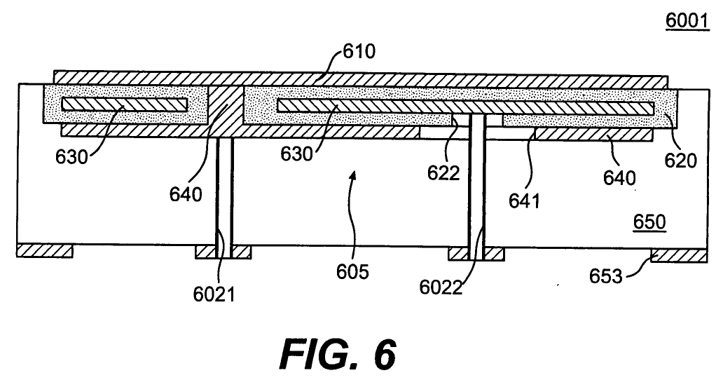

FIG. 6 is a sectional view of a sixth embodiment of an innerlayer panel 6001 including a capacitor 605. The capacitor 605 includes a first electrode 610 formed from a foil, a two-layer dielectric 620, a second electrode 630, and a third electrode 640. The capacitor 605 is laminated to a laminate material 650, and circuitry 653 may be formed over the laminate material 650 that allows connections to the capacitor 605 terminations by way of first and second circuit conductors 6021, 6022.

The first electrode 610 and the third electrode 640 are coupled to the first circuit conductor 6021, and the second electrode 630 is coupled to the second circuit conductor 6022. The termination of the second electrode 630 is located at a through-hole aperture 622 of the dielectric 620 that is coincident with a through-hole aperture 641 in the third electrode 640.

The capacitor 605 embodiment discussed above has the advantages of reduced termination separation and reduced surface area associated with locating the capacitor electrode terminations within the footprints of their respective electrodes. The capacitor 605 also has a high capacitance density because of the three-electrode, two-layer dielectric design.

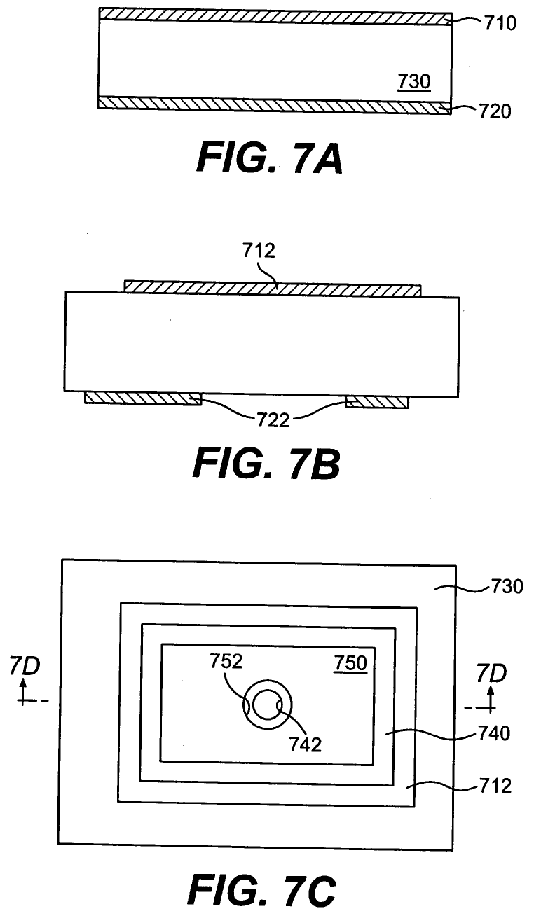

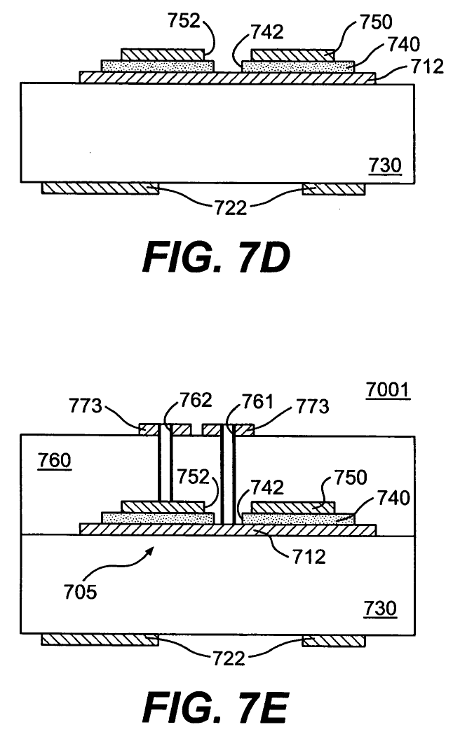

In the embodiments discussed above, polymer thick-film compositions designed to be dried at low temperatures, such as 150° C., may be used instead of thick-film compositions that are designed to be fired at elevated temperatures. The materials may be formed on a foil generally in the same manner as described above, but a curing step replaces the firing step. FIGS. 7A-7E illustrate an innerlayer panel embodiment and method using polymer thick-film compositions.

FIGS. 7A-7D illustrate a general method of manufacturing a seventh embodiment of an innerlayer panel 7001. FIG. 7E illustrates the completed innerlayer panel 7001, which includes a capacitor 705. The innerlayer panel 7001 is manufactured using polymer thick-film compositions to form the panel layers.

FIG. 7A is a sectional view of a first stage of manufacture of the innerlayer panel 7001. In FIG. 7A, an article is provided comprising a first foil 710 and a second foil 720 laminated to opposite sides of a laminate material 730. The first and second foils 710, 720 may be formed from polymer thick film materials. Because the polymer thick-film materials are cured at relatively low temperatures, such as 150° C., for example, a capacitor can be formed directly on the laminate material 730. Drying of the thick-film material is performed concurrently with curing.

Referring to FIG. 7B, the laminate article of FIG. 7A is etched to form a first electrode 712 from the foil 710. Circuitry 722 may also be formed from the foil 720 during the etching step.

FIGS. 7C and 7D illustrate a next stage of manufacture of the innerlayer panel 7001. FIG. 7C is a top plan view of the article formed at this stage of manufacture, and FIG. 7D is a sectional view in side elevation, taken on line 7D-7D in FIG. 7C. Referring to FIG. 7D, a dielectric 740 is formed over the first electrode 712. The dielectric 740 includes a clearance hole or aperture 742, and is formed from polymer thick-film material. One or more screen printing steps may be used to form the dielectric 740. The dielectric 740 is then cured. A second electrode 750 is formed over the dielectric 740 using polymer thick-film material. The second electrode 750 may be formed by, for example, depositing the polymer thick-film material in one or more screen printings, and subsequent curing. The second electrode 750 includes a clearance hole 752 coincident with the clearance hole 742, but of larger diameter (as shown in FIG. 7C).

The finished innerlayer panel 7001 is illustrated as a sectional view in side elevation in FIG. 7E. In FIG. 7E, the article resulting from the screen printing steps illustrated by FIGS. 7C and 7D is laminated, component-face down, to a laminate material 760. A foil may also be laminated to the laminate material 760, and the foil may be etched to form circuitry 773. The innerlayer panel 7001 therefore has a multi-layer subassembly configuration.

A first conductor 761 and a second conductor 762 are then formed by, for example, drilling and plating to form plated microvias. The first conductor 761 extends through the laminate material 760, and through the clearance apertures 742, 752 in the dielectric 740 and the second electrode 750, respectively. The first conductor 761 electrically connects to the first electrode 712, and the second conductor 762 electrically connects to the second electrode 750.

In the innerlayer panel 7001, the panel 7001 is a circuitized innerlayer or subassembly. Alternatively, an innerlayer panel can be formed using polymer thick-film compositions in which the innerlayer panel is part of a subset or larger subassembly of innerlayer panels, such as the fired-on-foil embodiments discussed above. In such an embodiment, circuit conductors may be formed after the innerlayer panel 7001 is combined with one or more innerlayer panels of a subassembly, the circuit conductors extending through all or part of the subassembly. An innerlayer panel having polymer thick-film layers can also be combined with one or more innerlayer panels to form a printed wiring board, such as is illustrated in FIG. 1I. In general the innerlayer panel embodiments discussed above that are formed by fired-on-foil methods can alternatively be formed using cured polymer thick-film compositions. Capacitors formed using polymer thick-film compositions are particularly useful, for example, in applications of low capacitance capacitors.

In the fired-on-foil embodiments discussed in this specification, the term “paste” may correspond to a conventional term used in the electronic materials industry, and generally refers to a thick-film composition. Typically, the metal component of the underprint paste is matched to the metal in the metal foil. For example, if a copper foil were used, then a copper-containing paste would be used as the underprint. Examples of other applications would be pairing silver and nickel foils with a similar metal underprint paste. Thick film pastes may be used to form both the underprint and passive circuit components.

Generally, thick-film pastes comprise finely divided particles of ceramic, glass, metal or other solids dispersed in polymers dissolved in a mixture of plasticizer, dispersing agent and organic solvent. Preferred capacitor pastes for use on fired-on copper foil applications have an organic vehicle with good burnout characteristics in a nitrogen atmosphere. Such vehicles generally contain very small amounts of resin, such as high molecular weight ethyl cellulose, where only small amounts are necessary to generate a viscosity suitable for screen-printing. Additionally, an oxidizing component such as, for example, a barium nitrate powder, blended into the dielectric powder mixture, would assist the organic component in burning out in the nitrogen atmosphere. Solids are mixed with an essentially inert liquid medium (the “vehicle”), then dispersed on a three-roll mill to form a paste-like composition suitable for screen-printing. Any essentially inert liquid may be used as the vehicle. For example, various organic liquids, with or without thickening and/or stabilizing agents and/or other common additives, may be used as the vehicle.

High dielectric constant (“high K”) thick-film dielectric pastes generally contain at least one high K functional phase powder and at least one glass powder dispersed in a vehicle system composed of at least one resin and one or more solvents. The vehicle system is designed to be screen-printed to provide a dense and spatially well-defined film. The high K functional phase powders can comprise perovskite-type ferroelectric compositions with the general formula ABO₃. Examples of such compositions include BaTiO₃; SrTiO₃; PbTiO₃; CaTiO₃; PbZrO₃; BaZrO₃ and SrZrO₃. Other compositions are also possible by substitution of alternative elements into the A and/or B position, such as Pb(Mg_{1/3} Nb_{2/3})O₃ and Pb(Zn_{1/3} Nb_{2/3})O₃. TiO₂ and SrBi₂Ta₂O₉ are other possible high K materials.

Doped and mixed metal versions of the above compositions are also suitable. Doping and mixing is done primarily to achieve the necessary end-use property specifications such as, for example, the necessary temperature coefficient of capacitance (TCC) in order for the material to meet industry definitions, such as “X7R” or “Z5U” standards.

The glasses in the pastes can be, for example, Ca—Al borosilicates, Pb—Ba borosilicates, Mg—Al silicates, rare earth borates, and other similar glass compositions. High K glass-ceramic powders, such as lead germanate ( Pb₅Ge₃O₁₁), are preferred materials.

Low K thick-film dielectric pastes can also be utilized in low impedance designs where low capacitance is required. In this case, the high K functional phase is replaced with, for example, neodynium titanate, titanium dioxide and barium titanate powder mixtures.

Pastes used to form the fired electrode layers may be based on metallic powders of either copper, nickel, silver, silver-containing precious metal compositions, or mixtures of these compounds. Copper powder compositions are preferred.

Polymeric thick-film pastes for use in cured-on components, such as those discussed above with reference to FIGS. 7A-7E, are generally composed of a permanent resin dissolved in an organic solvent that may contain dispersed finely divided particles of ceramic or metal. Plasticizers, dispersing agents or other additives may also be used. Preferred polymer thick-film capacitor pastes may be a pure resin, barium titanate or other high dielectric constant phases dispersed in solutions of epoxy or polyimide resins, for example. For the polymer thick-film embodiments discussed above, preferred polymer thick-film conductor pastes used to form the second electrode 750 in the innerlayer panel 7001 may be copper or silver powders dispersed in similar resins to that of a capacitor paste.

The innerlayer panel embodiments described in this specification have many applications. For example, the innerlayer panels embodiments can be used within organic printed circuit boards, IC packages, applications of these structures in decoupling applications, and devices such as IC modules and/or handheld device motherboards. Any of the innerlayer panel embodiments discussed above can be incorporated into a printed wiring board structure, and the innerlayer panel embodiments discussed above may be combined with other, conventional innerlayer panels to form a printed wiring board.

In the above embodiments, the conductive electrode layers are described as formed by screen-printing. Other methods, however, such as deposition by sputtering or evaporation of electrode metals onto the dielectric layer surface may also be used. The dielectric layers are also described as formed by screen printing, and may also be formed by alternative methods.

The shapes of the capacitor embodiments discussed above are generally rectangular when viewed in top plan view. However, the capacitor electrodes, dielectrics, and other capacitor components can have other surface area shapes, such as round or oval shapes, and polygonal shapes.

The foregoing description of the invention illustrates and describes the present invention. Additionally, the disclosure shows and describes only selected preferred embodiments of the invention, but it is to be understood that the invention is capable of use in various other combinations, modifications, and environments and is capable of changes or modifications within the scope of the inventive concept as expressed herein, commensurate with the above teachings, and/or within the skill or knowledge of the relevant art.

The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments, not explicitly defined in the detailed description.

What is claimed is:

1. A printed wiring board, comprising:
a first circuit conductor extending through at least a part of the printed wiring board;
a second circuit conductor extending through at least a part of the printed wiring board; and
a plurality of stacked innerlayer panels, wherein at least one of the innerlayer panels comprises:
a first electrode formed from a foil and having a termination, wherein the first circuit conductor is coupled to the first electrode at the termination of the first electrode, and wherein the first electrode termination is within a footprint of the first electrode;
at least one dielectric disposed over the first electrode; and
a second electrode spaced from the first electrode and having a termination, wherein the second electrode, the first electrode, and the dielectric form a capacitor, and wherein the second circuit conductor is coupled to the second electrode termination.

2. The printed wiring board of claim 1, wherein the first circuit conductor extends through the dielectric.

3. The printed wiring board of claim 2, wherein:
the second electrode termination is within a footprint of the second electrode; and
the second circuit conductor extends through the dielectric.

4. The printed wiring board of claim 2, the innerlayer comprising:
a laminate material disposed over the first and second electrodes and over the dielectric, wherein the first circuit conductor extends through the laminate material.

5. The printed wiring board of claim 4, wherein the second circuit conductor extends through the laminate material.

6. The printed wiring board of claim 2, the innerlayer comprising:
a third electrode spaced from the second electrode and electrically connected to the first electrode, and wherein the first electrode, the second electrode, the dielectric, and the third electrode form a capacitor.

7. The printed wiring board of claim 1, wherein the first electrode has a first component side that contacts the dielectric, and a second side opposite to the first side, and wherein the first circuit conductor extends from the second side of the first electrode.

8. The printed wiring board of claim 7, wherein the termination of the second electrode is within a footprint of the second electrode.

9. The printed wiring board of claim 7, the innerlayer comprising:
a laminate material disposed over the second side of the first electrode, wherein the first circuit conductor extends through the laminate material and the second circuit conductor extends through the laminate material.

10. The printed wiring board of claim 7, the innerlayer comprising:
a third electrode spaced from the second electrode and electrically connected to the first electrode, and wherein the first electrode, the second electrode, the dielectric, and the third electrode form a capacitor.

11. A method of making a printed wiring board, comprising:
forming a plurality of stacked innerlayer panels, wherein forming at least one of the innerlayer panels comprises:
providing a metallic foil;
forming a dielectric over the metallic foil;
forming a first electrode from the metallic foil, the first electrode having a termination located within a footprint of the first electrode; and
forming a second electrode over the dielectric, the second electrode having a termination, wherein the first electrode, the second electrode, and the dielectric form a capacitor;
forming a first circuit conductor, wherein the first circuit conductor extends through at least a portion of the printed wiring board and contacts the first electrode termination; and
forming a second circuit conductor, wherein the second circuit conductor contacts the second electrode termination and extends through at least a portion of the printed wiring board.

12. The method of claim 11, wherein forming a dielectric comprises:
forming a dielectric having a through-hole, the first circuit conductor extending through the through-hole.

13. The method of claim 12, wherein:
the second electrode termination is within a footprint of the second electrode; and
forming a second circuit conductor comprises forming a conductive via that extends through the dielectric.

14. The method of claim 12, wherein forming the innerlayer panel comprises:
forming a laminate material over the first and second electrodes and over the dielectric.

15. The method of claim 14, wherein:
forming the first circuit conductor comprises forming a conductive via through the laminate material; and
forming the second circuit conductor comprises forming a conductive via through the laminate material.

16. The method of claim 12, wherein forming the innerlayer panel comprises:
forming a third electrode spaced from the second electrode and electrically connected to the first electrode, wherein the first electrode, the second electrode, the third electrode and the dielectric form a capacitor.

17. The method of claim 12, wherein forming the innerlayer panel comprises:
providing a laminate material; and
laminating the metallic foil to the laminate material before forming the first electrode.

18. The method of claim 11, wherein the first electrode has a first component side that contacts the dielectric, and a second side opposite to the first side, wherein forming the first circuit conductor comprises:
forming the first circuit conductor to extend from the second side of the first electrode.

19. The method of claim 18, wherein:
the second electrode termination is within the footprint of the second electrode; and
forming the innerlayer panel comprises forming a laminate material over the second side of the first electrode.

20. The method of claim 19, wherein:
forming a first circuit conductor comprises forming a conductive via through the laminate material; and
forming a second circuit conductor comprises forming a conductive via through the laminate material.

21. The method of claim 18, wherein forming the innerlayer panel comprises:
forming a third electrode spaced from the second electrode and electrically connected to the first electrode, wherein the first electrode, the second electrode, the third electrode and the dielectric form a capacitor.

22. The method of claim 18, wherein forming the innerlayer panel comprises:
providing a laminate material; and
laminating the metallic foil to the laminate material before forming the first electrode.

23. The method of claim 11, wherein forming a plurality of stacked innerlayer panels comprises:
providing a specified number of innerlayer panels;
joining the innerlayer panels together;
forming a third circuit conductor through at least two of the joined innerlayer panels; and
incorporating the joined innerlayer panels into the printed wiring board.
